(19) United States
(12) Patent Application Publication
(10) Pub. No.: US 2015/0258895 A1
(43) Pub. Date: Sep. 17, 2015

(54) METHOD FOR CONTROLLING A FUNCTIONAL DEVICE OF A MOTOR VEHICLE

(71) Applicant: AUDI AG, Ingolstadt, (DE)

(72) Inventors: Tahar Bouaziz, Ingolstadt (DE); Werner Hamberger, Lenting (DE); Juergen Steinle, Ingolstadt (DE); Emanuel Angelescu, Ingolstadt (DE); Ulrich Mueller, Ingolstadt (DE)

(73) Assignee: AUDI AG, Ingolstadt (DE)

(21) Appl. No.: 14/428,540

(22) PCT Filed: Aug. 9, 2013
(86) PCT No.: PCT/EP2013/002393

§ 371 Date: Mar. 16, 2015

(30) Foreign Application Priority Data
Sep. 14, 2012 (DE) 10 2012 018 211.2

(51) Int. Cl. B60K 37/06; G01C 21/36; B60K 35/00

(52) U.S. Cl. CPC B60K 37/06; B60K 35/00; G01C 21/367; B60K 2350/102; B60K 2350/106

(57) ABSTRACT

A method controls a functional device of a motor vehicle by a control device. The control device has a rotary actuator which is rotationally mounted on a retaining element. The rotary actuator has at least one coding element. With the method an absolute rotational angle is detected between the rotary actuator and the retaining element based on a coding of the at least one coding element. A plurality of latch positions are defined for the rotary actuator in the rotational direction thereof. The respective latch position and the absolute rotational angle between two of the latch positions are detected, based on the coding of the at least one coding element. The functional device is controlled in accordance with the detected absolute rotational angle if the rotary actuator is between two of the latch positions.

### CROSS REFERENCE TO RELATED APPLICATIONS

This application is based on and hereby claims priority to International Application No. PCT/EP2013/002393 filed on Aug. 9, 2013 and German Application No. 10 2012 018 211.2 filed on Sep. 14, 2012, the contents of which are hereby incorporated by reference.

### BACKGROUND

The present invention relates to a method for operating a functional device for a motor vehicle having an operator control device.

In order to operate functional devices of a motor vehicle, corresponding operator control devices are provided. These can comprise a rotary actuator or rotary encoder. Contemporary rotary actuators have mechanical latched positions in which they latch along their rotational direction. These latched positions are perceived haptically by the user or the operator. In addition, an acoustic signal, for example a click, is also often output. This type of rotary actuator is widespread and is used, for example, in air-conditioning operator control components or the central input unit in the motor vehicle. As a rule, the rotary actuators are used to select values for a discrete function. For example, in an air-conditioning operator control component the temperature per latching stage is increased by a predefined temperature or the speed of a fan is raised.

Contemporary graphic user interfaces which are optimized for conventional rotary actuators are based in their system reaction on the discrete latched positions of the mechanical rotary actuators. Therefore, in graphics-based systems, such as a man-machine interface, the central rotary actuator is used for navigation in the display. In this context, adjustment of the rotary actuator by one latched position causes the screen display to shift by one increment upward or downward. In the case of a navigation system, adjusting the rotary actuator by one latched position can cause the map display to be enlarged or made smaller by one stage.

Consequently, the individual latched positions of the rotary actuator are initially fed back in a haptic and tactile fashion to an operator and frequently also acoustically by a click. Once this has taken place, the graphic display is then changed to a new system state. A short animation can also be provided between the changing of the display into the new system state. Owing to this defined sequence of system events, consequences of the user's action are always made visible only after the latched position of the rotary actuator has been reached. Correspondingly, the user cannot detect a faulty or undesired input with the rotary actuator until the system has been changed into a new state.

DE 10 2007 009 938 A1 describes an operator control device in a motor vehicle for selecting one of a plurality of objects which are arranged in a list. The operator control device comprises an input device which can be embodied as a turn and push actuator, and a display device. The display of the display device can be adapted as a function of the rotational direction and the rotational speed of the rotary actuator.

Furthermore, US 2011/061051 A1 describes a method for displaying information in a motor vehicle. An object can be represented in at least two display modes as a function of the signal of a control device which can be embodied as a rotary actuator. In a first display mode, a subset of the total information is displayed. In the second display mode the object is shown pivoted about an axis in a perspective or three-dimensional fashion relative to the first display mode of the object, wherein in the second display mode the subset of the total information which is represented by the object is larger than that in the case of the first display mode.

Furthermore, EP 1 075 979 A2 describes a method for operating a multi-function operator control device which comprises a display device and a rotary activation element. The rotary activation element is freely programmable in terms of rotational directions, rotational positions and/or latched positions and/or activation stops, in such a way that haptic feedback, which is assigned to respective menus or functions, is generated in the rotary activation path.

In addition, DE 10 2005 025 887 A1 discloses an operator control device for a motor vehicle having a turn and push operator control element. The turn and push operator control element is embodied in such a way that by its activation it is possible to move a marking element on a display device, wherein latched positions are predefined during a rotational movement of the turn and push operator control element.

DE 10 2009 057 950 A1 describes a setting device for a vehicle having an actuating device for setting a desired operating parameter which can assume a multiplicity of set positions between a minimum value and a maximum value. The actuating device can be embodied as a rotary regulator, wherein a position of a pointer on a display device changes in accordance with a set position of the rotary regulator.

Finally, DE 10 2008 057 098 A1 describes a rotary actuator for a vehicle which has a latching arrangement and a movement detection mechanism. The rotational direction and the rotational angle of an actuating element can be detected with a sensor device of the rotary actuator.

### SUMMARY

One possible object is to make the operating of a functional device of a motor vehicle with an operator control device easier and more intuitive.

The inventors propose a method for operating a functional device of a motor vehicle having an operator control device, wherein the operator control device comprises a rotary actuator which is rotatably mounted on a securing element and which has at least one coding element, comprises detecting an absolute rotational angle between the rotary actuator and the securing element on the basis of coding of the at least one coding element, predefining a multiplicity of latched positions for the rotary actuator along its rotational direction, detecting the respective latched position and the absolute rotational angle between at least two of the latched positions on the basis of the coding of the at least one coding element, and controlling the functional device as a function of the detected absolute rotational angle if the rotary actuator is located between two of the latched positions.

The operator control device can be arranged in the dashboard or in the center console of the motor vehicle. The motor vehicle can also comprise a plurality of operator control devices with which functional devices such as, for example, an air-conditioning system, a navigation system, an operator control device with associated display, an entertainment system or the like can be actuated. The operator control device comprises a rotary actuator which can also be embodied as a turn and push actuator. Furthermore, the operator control device comprises a latching device which predefines a plurality of latching stages or latching positions to the rotary actuator. At least one coding element, which can be detected with a detection device is arranged on the rotary actuator. The detection device of the operator control device is then designed to detect the predefined latched positions individually on the basis of the coding of the at least one coding element. In addition, the absolute rotational angle between at least two latched positions can be detected with the detection device. Furthermore, the rotational direction of the rotary actuator can be detected with the detection device on the basis of the coding of the at least one coding element. The discrete latched positions, which give rise to a sensation of high-quality operator control for the user as a result of the haptic feedback, are present at the operator control device. Furthermore, slight deflections of the rotary actuator before the latching in the next latched position can be detected with the detection device. As a result, in addition to the latched positions the intermediate positions between the latching stages can also be detected with high resolution and a corresponding control signal for operating the functional device can also be output in a simple manner.

A latching control signal for controlling the functional device is preferably output for each of the detected latched positions. Settings of functional devices for the motor vehicle which occur in discrete steps or stages can be made available with the respective latching control signal. Simple and intuitive operator control can be made possible by the individual latching stages and the associated actuation of the functional device. In addition, an impression of particularly high quality is produced for the operator.

In a further embodiment, at least one intermediate control signal for controlling the functional device is output as a function of the detected rotational angle between the two latched positions. Slight deflections in the rotary actuator before the latching into the next latched position can be detected with the operator control device. As a result, in addition to the latched positions the intermediate positions between the latching stages can also be detected with high resolution and corresponding intermediate control signals for controlling the functional device can be output in a simple manner. In this way, the functionality of the operator control device can be extended.

In a further refinement a multiplicity of intermediate positions is defined between the two latched positions, wherein an intermediate control signal for controlling the functional device is output for each of the intermediate positions. The functionality of the operator control device is additionally extended by the individual intermediate stages. If a sufficient number of intermediate positions is provided, almost continuous operation of a functional device can be made possible. In addition, the operator can be informed about his action in many intermediate steps.

Furthermore, it is advantageous if the functional device comprises a display device, wherein a display on the display device is adapted as a function of the latching control signals and/or the at least one intermediate control signal. The individual latched positions of the rotary actuator can be coupled directly to the graphic latching stages of the display on the display device. It is therefore possible to synchronize the latched positions with predefined displays. By the intermediate signals and the associated change in the display it is possible for an operator to receive a faster clarification about the consequences of their operator control action. In addition, the operator control device is perceived to have a significantly higher quality by virtue of the delay-free and almost infinitely variable implementation of commands.

In a further embodiment, the display on the display device is enlarged or made smaller by a predefined first factor by each of the latching control signals. This permits, for example, incremental zooming in a map display of a navigation system. In this context it is also conceivable that a display on the display device is correspondingly shifted by each of the latching control signals. Easy and fast operator control of the functional device can be made possible by the individual latching control signals.

The display is preferably enlarged or made smaller by a predefined second factor by the at least one intermediate control signal, wherein the second factor is smaller than the first factor. In this context there is also provision that the portion of the display on the display device is adapted to the increase or decrease in the size of the display. In this context, a plurality of intermediate positions also can be provided between two latching stages, wherein the display is enlarged or made smaller by a predefined factor by each of the intermediate control signals. In this context, the factors for the increase or decrease in size which is brought about by the intermediate control signals and latching control signals can be selected in such a way that during the rotation of the rotary actuator an almost continuous increase or decrease in size of the display occurs. As a result, a fluid change in scale parallel to the movement of the rotary actuator occurs.

In a further refinement, a multiplicity of list entries and a selection element for selecting one of the list entries are displayed on the display device, wherein a display of the selection element is shifted by a predefined first number of list entries by each of the latching control signals. In this context it is also possible to provide that the display of the selection element is shifted by just one list entry by a latching control signal. In this way, the individual list entries can be reliably selected by the operator, resulting in easy operator control.

The display of the selection element is preferably shifted by a predefined second number of list entries by the at least one intermediate control signal, wherein the second number is smaller than the first number. In this way, almost continuous movement of the selection element between the individual list entries occurs as a result of the rotation of the rotary actuator. If a multiplicity of intermediate positions is provided between two latching stages, the speed of the shifting of the display of the selection element can be adapted as a function of the rotational speed of the rotary actuator. In other words, the scrolling speed in a list can be set with the rotary actuator. This permits easy and intuitive operator control of a list.

Finally, it is advantageous if the display of the selection element is shifted into a position between two of the list entries by the least one intermediate control signal. In this way, when activating the rotary actuator the operator is provided with immediate feedback about their operator control action. The operator can, for example, recognize directly whether the selection element or a pointer in the list is shifted upward or downward in the list by the instantaneous rotational movement of the rotary actuator. In this way, in particular the operator control of vertical lists can be simplified.

### BRIEF DESCRIPTION OF THE DRAWINGS

These and other objects and advantages of the present invention will become more apparent and more readily appreciated from the following description of the preferred embodiments, taken in conjunction with the accompanying drawings of which:

FIG. 1 shows a schematic illustration of an operator control device in a sectional side view;

FIG. 2 shows a schematic illustration of the operator control of a functional device with an operator control device; and

FIG. 3 shows a schematic illustration of the operator control of a further functional device with the operator control device.

### DETAILED DESCRIPTION OF THE PREFERRED EMBODIMENT

Reference will now be made in detail to the preferred embodiments of the present invention, examples of which are illustrated in the accompanying drawings, wherein like reference numerals refer to like elements throughout.

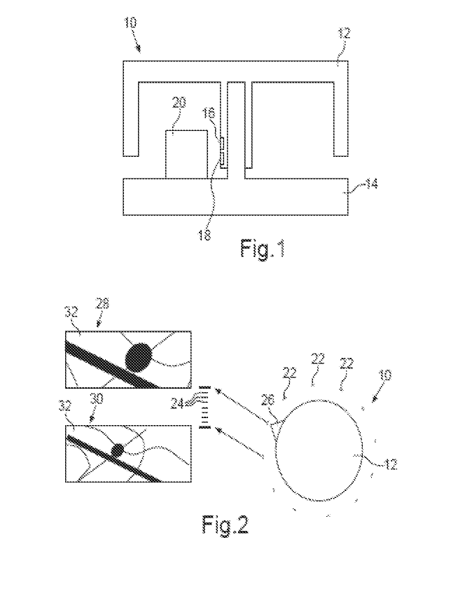

FIG. 1 shows a schematic illustration of an operator control device 10 in a sectional side view. The operator control device 10 serves to operate a functional device of a motor vehicle. Such a functional device can be an air-conditioning system, a navigation system, an operator control device with associated display, an entertainment system or the like. The operator control device 10 comprises a rotary actuator 12 which is rotatably mounted on a securing element 14. Furthermore, two coding elements 16 and 18 are arranged on the rotary actuator 12. The coding elements 16, 18 can comprise one or more magnets. Alternatively, the coding elements 16, 18 can comprise electrical contacts. In a further embodiment, the coding elements 16, 18 can comprise corresponding recesses.

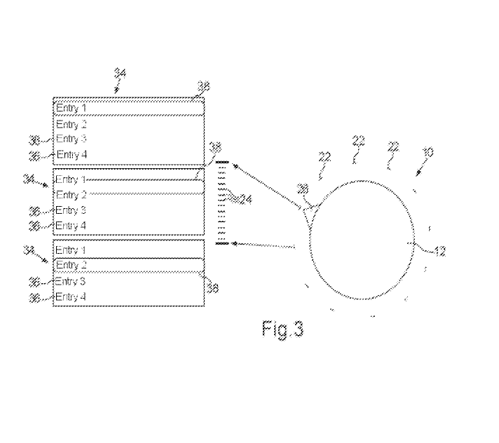

Furthermore, the operator control device 10 comprises a detection device 20 which is connected to the securing element 14 in a mechanically fixed fashion. The detection device 20 can comprise a corresponding sensor element which interacts with the coding elements 16, 18 in such a way that in each case an output signal is made available by the detection device 20 as a function of coding of the coding elements 16, 18. If the coding elements 16, 18 comprise magnets, the detection device 20 can have a magnetic sensor, for example a Hall sensor. If the coding elements 16, 18 have electrical contacts, the detection device 20 can comprise slip contacts. If the coding elements 16, 18 are formed by recesses, the detection device 20 can comprise an optical sensor. The operator control device 10 additionally has a latching device (not illustrated here) by which latched positions 22 are predefined to the rotary actuator 12 (see FIGS. 2 and 3).

At least two output signals are generated by the two coding elements 16 and 18 in the detection device 20 as a result of the rotation of the rotary actuator 12. In this context, the coding elements 16, 18 can be embodied in such a way that two output signals are produced and said output signals have an essentially continuous or analog profile. The output signals can also be offset with respect to one along their rotational direction. In each case a threshold value can be predefined for the evaluation of these analog output signals. The rotational direction and the individual latched position 22 can be determined as a function of the exceeding or undershooting of the threshold value. Furthermore, on the basis of the output signals it is possible to determine the rotational angle between at least two latched positions 22. The respective amplitude of the output signal is used to determine the rotational angle in a range between at least two latched positions 22.

Three coding elements 16, 18 can also be used, wherein the coding elements 16, 18 can be configured here in such a way that as a result of the detection of two of the three coding elements 16, 18 the detection device 20 outputs a digital output signal in each case. On the basis of the digital output signals, the rotational direction and the individual latched position can be determined. By the evaluation of the third of the three coding elements 16, 18, the detection device 20 outputs an output signal which has a continuous or analog profile. The rotational angle between two of the latched positions 22 can be determined on the basis of the output signal.

If the rotary actuator 12 is located in one of the latched positions 22, a latching control signal is output by the operator control device 10. In this context, a separate latching control signal is output for each of the latched positions 22. These latching control signals serve to actuate a functional device of the motor vehicle. If the rotary actuator 12 is located between two of the latched positions 22, at least one intermediate control signal is output, said intermediate control signal also serving to actuate the functional device. The intermediate control signal can be generated as a function of the rotational angle between two latched positions 22. A multiplicity of intermediate positions 24 is preferably defined between every two latched positions 22, wherein an intermediate controlled signal is generated for each intermediate position 24 as soon as the rotary actuator 12 is moved into the respective intermediate position 24.

FIG. 2 shows a schematic display which clarifies the operator control of a functional device with the operator control device 10. The operator control device 10 is illustrated here in a plan view. The rotary actuator 12 has a position element 26 which characterizes the current position of the rotary actuator. The operator control device 10 is used here to control a navigation system, and, in particular, a map display on a display device of the navigation system. In the instantaneous latched position 22 of the rotary actuator 12, a first representation 28 of the display 32 is displayed on the display device. The display 32 can be enlarged or made smaller by the rotation of the rotary actuator 12, depending on the rotational direction.

If the rotary actuator 12 is rotated in the counterclockwise direction into the next latched position 22, the latching control signal which is associated with this latched position 22 is output, as a result of which the representation 30 of the display 32 is displayed on the display device, on which the display 32 is made smaller by a predetermined factor compared to the representation 28. In addition, the detail of the display 32 is correspondingly adapted. In this context it is also possible to provide that the display 32 is enlarged or made smaller as a function of the intermediate control signals in the intermediate positions 24, wherein the display 32 is enlarged or made smaller by a smaller factor. This makes it possible that an operator or the driver does not rotate the rotary actuator 12 from one latched position 22 directly into the next latched position 22 but rather firstly rotates it into one of the intermediate positions 24 between the latched positions 22. As a result of the outputting of the corresponding intermediate control signal and the associated changing of the display 32, the operator can immediately recognize whether the rotational direction into which he is currently rotating the rotary actuator 12 causes the display 32 to become larger or smaller. If the operator rotates the rotary actuator 12 from a latched position 22 in the counterclockwise direction in one of the intermediate positions 24, he is immediately informed that this rotational movement causes the display 32 to become smaller. If the operator desires this, he can rotate the rotary actuator 12 into the next latched position 22. If he wishes to enlarge the display 32, he can continue to rotate the rotary actuator 12 in the clockwise direction.

If a corresponding number of intermediate positions 24 is provided between the latched positions 22, a display can be made possible in which the display 32 is almost continuously enlarged or made smaller during a rotation of the rotary actuator. This makes it possible for the operator or the driver to change the display 32 at short notice by moving the rotary actuator 12 into the intermediate positions 24. This is the case, for example, if the operator would like to have a map detail instantaneously displayed in an enlarged fashion. In the latched positions 22, a stable enlargement stage or zoom stage of the display 32, which he can use, for example, for navigation, is displayed to the operator.

FIG. 3 illustrates the operator control of a functional device with the operator control device 10 using the example of a list. A representation 34 with a multiplicity of list entries 36 is displayed on the display device. In addition, a selection element 38, with which the respective list entry 36 can be selected is displayed. In the instantaneous latched position 22, the selection element 38 is located above the list entry 36 “entry 1”. If the operator or the driver rotates the rotary actuator in the counterclockwise direction into the next latched position 22, the selection element is moved to the list entry 36 “entry 2”. If the rotary actuator 12 is located in one of the intermediate positions 24 between these two latched positions 22, the selection element 38 is displayed between the two list entries 36 “entry 1” and “entry 2”. By rotating the rotary actuator 12 into one of the intermediate positions 24, the operator immediately receives feedback as to whether the selection element 38 moves upward or downward as a result of this rotation. In addition, owing to the rotation of the rotary actuator 12 a continuous movement of the selection element 38 between the individual list entries 36 occurs.

The invention has been described in detail with particular reference to preferred embodiments thereof and examples, but it will be understood that variations and modifications can be effected within the spirit and scope of the invention covered by the claims which may include the phrase “at least one of A, B and C” as an alternative expression that means one or more of A, B and C may be used, contrary to the holding in Superguide v. DIRECTV, 69 USPQ2d 1865 (Fed. Cir. 2004).

1-10. (canceled)

11. A method for operating a functional device of a motor vehicle, the motor vehicle having an operator control device, the operator control device comprising a rotary actuator which is rotatably mounted on a securing element and which has at least one coding element, the method comprising:
predefining a plurality of latched positions along a rotational direction of the rotary actuator;
detecting a current latching position of the rotary actuator and detecting an absolute rotational angle between the rotary actuator and the securing element, the absolute rotational angle being a rotational angle between two latched positions of the plurality of latched positions, the current latching position and the absolute rotational angle being detected based on a coding of the at least one coding element; and
controlling the functional device as a function of the absolute rotational angle if the rotary actuator is located between the two latched positions.

12. A method according to claim 11, wherein
a latching control signal for controlling the functional device is output for each latched position that is detected.

13. A method according to claim 11, wherein
the rotary actuator is located between adjacent latched positions, and
an intermediate control signal for controlling the functional device is output as a function of the rotational angle between the two adjacent latched positions.

14. A method according to claim 11, wherein
a plurality of intermediate positions are defined between each pair of adjacent latched positions, and
an intermediate control signal for controlling the functional device is output for each of the intermediate positions.

15. A method according to claim 14, wherein
the operator control device produces an output signal, and
the plurality of intermediate position includes a number of intermediate positions selected so that the output signal has a substantially continuous analog profile, fluid changes are made to the functional device in a substantially continuously variable manner and a perceived delay-free implementation of commands is provided to a user before the rotary actuator reaches a new latched position.

16. A method according to claim 12, wherein
an intermediate control signal for controlling the functional device is output as a function of the rotational angle between the two latched positions,
the functional device comprises a display device, and
a display on the display device is adapted as a function of at least one of the latching control signal and the intermediate control signal.

17. A method according to claim 16, wherein
the display on the display device is enlarged or made smaller by a predefined first factor each time the latching control signal is output.

18. A method according to claim 16, wherein
a plurality of list entries and a selection element for selecting one of the list entries are displayed on the display device,
the selection element is shifted to a different list entry on the display device to select one of the list entries, and
the selection element is shifted by a predefined first number of list entries each time the latching control signal is output.

19. A method according to claim 16, wherein
a plurality of list entries and a selection element for selecting one of the list entries are displayed on the display device,
the selection element is shifted to a different list entry on the display device to select one of the list entries, and
the selection element is shifted into a position between two list entries by the intermediate control signal.

20. A method according to claim 12, wherein
a plurality of intermediate positions are defined between each pair of adjacent latched positions,
an intermediate control signal for controlling the functional device is output for each of the intermediate positions,
the functional device comprises a display device, and
a display on the display device is adapted as a function of at least one of the latching control signal and the intermediate control signal.

21. A method according to claim 20, wherein
the display on the display device is enlarged or made smaller by a predefined first factor each time the latching control signal is output.

22. A method according to claim 21, wherein
the display on the display device is enlarged or made smaller by a predefined second factor each time the intermediate control signal is output, the second factor being smaller than the first factor.

23. A method according to claim 22, wherein
rotating the rotary actuator in a first direction enlarges the display, and
rotating the rotary actuator in a second direction, opposite to the first direction, makes the display smaller.

24. A method according to claim 23, wherein
the display device displays a map of a navigation system, and
the map is enlarged or made smaller by rotating the rotary actuator in the first or second direction, respectively.

25. A method according to claim 20, wherein
a plurality of list entries and a selection element for selecting one of the list entries are displayed on the display device,
the selection element is shifted to a different list entry on the display device to select one of the list entries, and
the selection element is shifted by a predefined first number of list entries each time the latching control signal is output.

26. A method according to claim 25, wherein
the selection element is shifted by a predefined second number of list entries each time the intermediate control signal is output, wherein the second number is smaller than the first number.

27. A method according to claim 25, wherein
for each pair of adjacent latched positions, at least one intermediate position is associated with an intermediate control signal that shifts the selection element into a position between two list entries.

28. A method according to claim 11, wherein
a detection device detects the current latching position and the absolute rotational angle, and
the operator control device is configured as one of the following:
magnets are provided as the at least one coding element and a magnetic sensor is provided as the detection device,
electrical contacts are provided as the at least one coding element and slip contacts are provided as the detection device, and
recesses are provided as the at least one coding element and an optical sensor is provided as the detection device.

29. A method according to claim 11, wherein the rotary actuator has at least two coding elements that are offset from one another with respect to the rotational direction of the rotary actuator.

30. A method according to claim 11, wherein the rotary actuator is a turn-and-push actuator that controls the functional device both when turned and when pushed.
